(19) United States
(12) Patent Application Publication
(10) Pub. No.: US 2022/0005939 A1
(43) Pub. Date: Jan. 6, 2022

(54) SEMICONDUCTOR DEVICE AND FABRICATION METHOD THEREOF

(71) Applicant: INNOSCIENCE (ZHUHAI) TECHNOLOGY CO., LTD., Zhuhai City (CN)

(72) Inventor: Han-Chin CHIU, Zhuhai City (CN)

(21) Appl. No.: 17/042,927

(22) PCT Filed: Jul. 1, 2020
(86) PCT No.: PCT/CN2020/099696

§ 371 Date: Sep. 29, 2020

(51) Int. Cl. H01L 29/66; H01L 29/20; H01L 29/778

(52) U.S. Cl. CPC H01L 29/66462; H01L 29/7787; H01L 29/2003

(57) ABSTRACT

The present disclosure relates to a semiconductor device and a fabrication method thereof. The semiconductor device includes a substrate, a first nitride semiconductor layer above the substrate, a semiconductor stack disposed on and in contact with the first nitride semiconductor layer, and a first electrode in contact with the semiconductor stack. Wherein the semiconductor stack comprises a first layer and a second layer, and a lattice constant of the first layer along an a-axis is less than the second layer.

### BACKGROUND

### 1. Technical Field

The present disclosure relates to the semiconductor field, more particularly to a high electron mobility transistor (HEMT) having high carrier concentration and high carrier mobility, and a fabrication method thereof.

### 2. Description of the Related Art

A high electron mobility transistor (HEMT) is a field effect transistor. A HEMT is different from a metal-oxide-semiconductor (MOS) transistor in that the HEMT adopts two types of materials having different bandgaps that form a heterojunction, and the polarization of the heterojunction forms a two-dimensional electron gas (2DEG) region in the channel layer for providing a channel for the carriers. HEMTs have drawn a great amount of attention due to their excellent high frequency characteristics. HEMTs can operate at high frequencies because the current gain of HEMTs can be multiple times better than MOS transistors, and thus can be widely used in various mobile devices.

Research is continuously conducted by adopting different materials in the manufacturing of HEMTs, for the purpose of achieving HEMTs that can have better current gain characteristics.

### SUMMARY

According to some embodiments of the present disclosure, a semiconductor device is provided, including a substrate, a first nitride semiconductor layer above the substrate, a semiconductor stack disposed on and in contact with the first nitride semiconductor layer, and a first electrode in contact with the semiconductor stack.

Wherein the semiconductor stack comprises a first layer and a second layer, and a lattice constant of the first layer along an a-axis is less than the second layer.

According to some embodiments of the present disclosure, a semiconductor device is provided, including a substrate, a first nitride semiconductor layer disposed above the substrate, a semiconductor stack disposed on the channel layer, and a first electrode in contact with the semiconductor stack. Wherein the semiconductor stack comprises a second nitride semiconductor layer and a third nitride semiconductor layer, and a bandgap of the second nitride semiconductor layer is different from a bandgap of the third nitride semiconductor layer.

According to some embodiments of the present disclosure, a method for fabricating a semiconductor device is provided. The method comprises providing a semiconductor structure having a substrate and a channel layer above the substrate, providing a first nitride semiconductor layer on the channel layer, providing a second nitride semiconductor layer above the first barrier layer, and providing an electrode in contact with the second nitride semiconductor layer. Wherein the first nitride semiconductor layer comprises AlₓGa₁₋ₓN, and the second nitride semiconductor layer comprises In_{y}Al_{1-y}N

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 illustrates a cross-sectional view of a semiconductor device according to some embodiments of the present disclosure;

FIG. 2 illustrates a cross-sectional view of a semiconductor device according to some embodiments of the present disclosure;

FIG. 3 illustrates a cross-sectional view of a semiconductor device according to some embodiments of the present disclosure;

FIG. 4A illustrates a semiconductor stack and the structural relationship between an electrode and the channel layer, according to some embodiments of the present disclosure;

FIG. 4B illustrates a semiconductor stack and the structural relationship between an electrode and the channel layer, according to some embodiments of the present disclosure;

FIG. 4C illustrates a semiconductor stack and the structural relationship between an electrode and the channel layer, according to some embodiments of the present disclosure;

FIG. 4D illustrates a semiconductor stack and the structural relationship between an electrode and the channel layer, according to some embodiments of the present disclosure;

FIG. 4E illustrates a semiconductor stack and the structural relationship between an electrode and the channel layer, according to some embodiments of the present disclosure;

FIG. 4F illustrates a barrier layer and the structural relationship between an electrode and the channel layer, according to some embodiments of the present disclosure;

FIGS. 5A, 5B, 5C, 5D, 5E, 5F, 5G and 5H illustrate operations for fabricating a semiconductor device according to some embodiments of the present disclosure;

FIGS. 6A, 6B, 6C, 6D, 6E, 6F, 6G and 6H illustrate operations for fabricating a semiconductor device according to some embodiments of the present disclosure.

### DETAILED DESCRIPTION

Embodiments of the present disclosure are discussed in detail below. It should be appreciated, however, that the present disclosure provides many applicable concepts that can be embodied in a wide variety of specific contexts. It should be appreciated that the following disclosure provides for many different embodiments, or examples, for implementing different features of the provided subject matter. Specific examples of components and arrangements are described below. These are, of course, merely examples and are not intended to be limiting.

The following embodiments or examples as illustrated in the drawings are described using a specific language. It should be appreciated, however, that the specific embodiments discussed are merely illustrative and do not limit the scope of the disclosure. In addition, it should be appreciated by persons having ordinary skill in the art that any changes and/or modifications of the disclosed embodiments as well as any further applications of the principles disclosed herein are encompassed within the scope of the present disclosure.

In addition, the present disclosure may repeat reference numerals and/or letters in the various examples. This repetition is for the purpose of simplicity and clarity and does not in itself dictate a relationship between the various embodiments and/or configurations discussed.

Gallium nitride (GaN) is anticipated to be the key material for a next generation power semiconductor device, having the properties of a higher breakdown strength, faster switching speed, higher thermal conductivity, lower on-resistance (Rₒₙ) and higher current gain. Power devices which include this wide-bandgap semiconductor material can significantly outperform the traditional Si-based power chips (for example, MOSFETs). Radio frequency (RF) devices which include this wide-bandgap semiconductor material can significantly outperform the traditional Si-based RF devices. As such, GaN-based power devices/RF devices will play a key role in the market of power conversion products and RF products, which includes battery chargers, smartphones, computers, servers, base stations, automotive electronics, lighting systems and photovoltaics.

A higher current gain characteristic is preferable for GaN HEMTs in an RF device. In recent years, the InAlN-based GaN HEMTs have become more and more popular, especially in RF devices due to their higher carrier concentration resulting in high current density. In the InAlN/GaN heterojunction of InAlN-based GaN HEMTs, higher quantum well polarization charges can be induced, which can reduce channel resistance and result in higher HEMT drive currents. In addition, InAlN possesses the widest range of bandgaps in the nitride system, which can be beneficial for carrier confinement to the device channel.

Compared to AlGaN-based GaN HEMTs, the InAlN-based GaN HEMTs have nearly three times higher carrier concentration. A nitride layer of GaN HEMTs including In_{0.83}Al_{0.17}N was proposed in 2001. Since In_{0.83}Al_{0.17}N's lattice constant is matched with GaN's lattice constant, In_{0.83}Al_{0.17}N is a very attractive material to be used in GaN HEMTs that are expected to have higher performance. However, there are still many challenges that InAlN-based GaN HEMTs need to overcome. Issues regarding crystal quality, surface morphology, and thermal stability that may be encountered during mass production cause InAlN-based GaN HEMT products to be difficult to realize. For example, the crystal quality of InAlN directly grown on a GaN channel will degrade the electron mobility near the InAlN/GaN heterojunction, which is not favorable for device performance.

Therefore, there is a need to develop an InAlN-based GaN HEMT having higher carrier concentration while not sacrificing the carrier mobility.

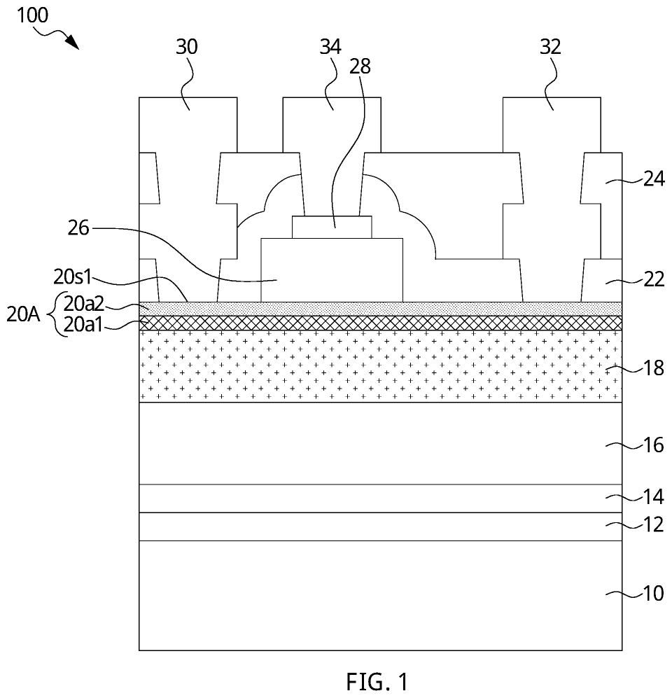

FIG. 1 illustrates a cross-sectional view of a semiconductor device according to some embodiments of the present disclosure. The HEMT 100 shown in FIG. 1 can be an enhanced mode (E-mode) HEMT. The HEMT 100 may include a substrate 10, a seed layer 12, a buffer layer 14, an electron blocking layer (EBL) 16, a channel layer 18, a barrier layer 20A, passivation layers 22 and 24, a semiconductor gate 26, and a gate conductor 28 disposed on the semiconductor gate 26. The semiconductor gate 26 and the gate conductor 28 may form the gate of the HEMT 100.

The HEMT 100 further includes electrodes 30 and 32 in contact with the barrier layer 20A. An ohmic contact may be formed between electrode 30 and the barrier layer 20A. An ohmic contact may be formed between electrode 32 and the barrier layer 20A. The HEMT 100 further includes an electrode 34 in contact with the gate conductor 28. The electrodes 30 and 32 may form the source/drain electrodes of the HEMT 100.

The substrate 10 may include, for example, but is not limited to, silicon (Si), doped Si, silicon carbide (SiC), germanium silicide (SiGe), gallium arsenide (GaAs), or other semiconductor materials. The substrate 10 may include, for example, but is not limited to, sapphire, silicon on insulator (SOI), or other suitable materials. The substrate 10 may include a silicon material. The substrate 10 may be a silicon substrate.

The seed layer 12 is disposed on the substrate 10. The seed layer 12 may help to compensate for a mismatch in lattice structures between substrate 10 and the electron blocking layer 16. The seed layer 12 includes multiple layers. comprise seed layer 12 includes a same material formed at different temperatures. comprise seed layer 12 includes a step-wise change in lattice structure. comprise seed layer 12 includes a continuous change in lattice structure. comprise seed layer 12 is formed by epitaxially growing the seed layer on substrate 10.

The seed layer 12 can be doped with carbon. In some embodiments, a concentration of carbon dopants ranges from about 2×10¹⁷ atoms/cm³ to about 1×10²⁰ atoms/cm³. The seed layer 12 can be doped using an ion implantation process. The seed layer 12 can be doped using an in-situ doping process. The seed layer 12 can be formed using molecular oriented chemical vapor deposition (MOCVD), molecular beam epitaxy (MBE), hydride vapor phase epitaxy (HYPE), atomic layer deposition (ALD), physical vapor deposition (FM) or another suitable formation process. The in-situ doping process includes introducing the carbon dopants during formation of the seed layer 12. A source of the carbon dopants includes a hydrocarbon (CₓH_{y}) such as CH₄, C₇H₇, C₁₆H₁₀, or another suitable hydrocarbon. The source of the carbon dopants includes CBr₄, CCl₄, or another suitable carbon source.

As illustrated in FIG. 1, the HEMT 100 includes a buffer layer 14 formed on the seed layer 12. The buffer layer 14 may include GaN, AlGaN, or aluminum nitride (AlN) and provides an interface from the non-GaN substrate to a GaN-based active structure. The buffer layer 14 reduces defect concentration in the active device layers.

The electron blocking layer 16 may be disposed on the buffer layer 14. The electron blocking layer 16 may include a group III-V layer. The electron blocking layer 16 may include, for example, but is not limited to, group III nitride. The electron blocking layer 16 may include a compound Al_{y}Ga_{(1-y)}N, in which y≤1. The electron blocking layer 16 may have a bandgap that is greater than that of the channel layer 18.

The channel layer 18 may be disposed on the electron blocking layer 16. The channel layer 18 may include a group III-V layer. The channel layer 18 may include, for example, but is not limited to, group III nitride. The channel layer 18 may include a compound Al_{y}Ga_{(1-y)}N, in which y≤1. The channel layer 18 may include GaN. The channel layer 18 can also be referred to as a nitride semiconductor layer if the channel layer 18 contains nitride.

The barrier layer 20A may be disposed on the channel layer 18. The barrier layer 20A may have a bandgap that is greater than that of the channel layer 18. A heterojunction may be formed between the barrier layer 20A and the channel 18. The polarization of the heterojunction of different nitrides forms a two-dimensional electron gas (2DEG) region in the channel layer 18. The 2DEG region is usually formed in the layer that has a lower bandgap (e.g., GaN).

The barrier layer 20A may include multiple layers. The barrier layer 20A may be a semiconductor stack. The barrier layer 20A may be a semiconductor stack including layer 20a1 and layer 20a2. The barrier layer of the HEMT 100 can be a semiconductor stack including more than two layers.

The layer 20a1 may include a group III-V layer. The layer 20a1 may include, for example, but is not limited to, group III nitride. The layer 20a1 may include a compound Al_{y}Ga_{(1-y)}N, in which 0≤y≤1. The layer 20a1 may include a compound Al_{y}Ga_{(1-y)}N, in which 0.1≤y≤0.35. In some embodiments, a material of the layer 20a1 may include AlGaN. In some embodiments, a material of the layer 20a1 may include undoped AlGaN. The layer 20a1 can also be referred to as a nitride semiconductor layer if the layer 20a1 contains nitride.

The layer 20a2 may include a group III-V layer. The layer 20a2 may include, for example, but is not limited to, group III nitride. The layer 20a2 may include a compound InₓAl₍₁₋ₓ₎N, in which 0≤x≤1. The layer 20a2 may include a compound InₓAl₍₁₋ₓ₎N, in which 0.1≤x≤0.3. The layer 20a2 may include a compound InₓAl₍₁₋ₓ₎N, in which 0.1≤x≤0.6. In some embodiments, a material of the layer 20a2 may include InAlN. In some embodiments, a material of the layer 20a2 may include undoped InAlN. The layer 20a2 can also be referred to as a nitride semiconductor layer if the layer 20a2 contains nitride.

The bandgap of the layer 20a1 may change in accordance with the concentrations of the materials of the layer 20a1. The bandgap of the layer 20a2 may change in accordance with the concentrations of the materials of the layer 20a2. The layer 20a1 may have a bandgap substantially identical to that of the layer 20a2. The layer 20a1 may have a bandgap different from that of the layer 20a2. The layer 20a1 may have a bandgap greater than that of the layer 20a2. The layer 20a2 may have a bandgap greater than that of the layer 20a1.

The layer 20a1 can be in direct contact with the channel layer 18. The layer 20a2 can be in direct contact with the electrodes 30 and 32.

The material of the layer 20a1 can have a higher growth temperature than that of the layer 20a2. The material of the layer 20a1 grown under a higher temperature can have good crystal quality. The material of the layer 20a1 grown under a higher temperature can have high carrier mobility.

The layer 20a2 can be grown under a lower temperature. The materials of the layer 20a2 are such that the Oxides do not tend to be generated on the layer 20a2. As a result, additional steps such as passivation treatment can be eliminated from the manufacturing of the HEMT 100, and a lower manufacturing cost can be expected. The layer 20a2 can have a relatively low energy bandgap compared to that of the layer 20a1, and thus it would be easier for the electrodes 30 and 32 to be formed on the layer 20a2. The layer 20a2 grown under a lower temperature can have a relatively rough upper surface 20s1. The relatively rough upper surface 20s1 of the layer 20a2 may facilitate the formation of the electrodes 30 and 32.

The layer 20a1 can have a thickness in a range of 0.5 to 20 nanometers (nm). The layer 20a2 can have a thickness in a range of 0.5 to 25 nm.

The lattice constant of the layer 20a1 can be different from the lattice constant of the layer 20a2. The lattice constant of the layer 20a1 along the a-axis can be different from the lattice constant of the layer 20a2 along the a-axis. The lattice constant of the layer 20a1 along the a-axis is less than the lattice constant of the layer 20a2 along the a-axis.

The lattice constant along the a-axis of the layer 20a1 ranges from approximately 3.1 Å to approximately 3.18 Å. The lattice constant along the a-axis of the layer 20a2 ranges from approximately 3.2 Å to approximately 3.5 Å.

The electrodes 30 and 32 can be in contact with the barrier layer 20A. The electrodes 30 and 32 are in contact with the layer 20a2. The electrodes 30 and 32 each includes a portion embedded in the passivation layer 22. The electrodes 30 and 32 each includes a portion embedded in the passivation layer 24. The electrodes 30 and 32 may include, for example, but are not limited to, titanium (Ti), aluminum (Al), Nickel (Ni), Gold (Au), Palladium (Pd), or any combinations or alloys thereof.

The semiconductor gate 26 may be disposed on the barrier layer 20A. The semiconductor gate 26 may be in contact with the layer 20a2. The semiconductor gate 26 may include a group III-V layer. The semiconductor gate 26 may include, for example, but is not limited to, group III nitride. The semiconductor gate 26 may include a compound Al_{y}Ga_{(1-y)}N, in which y≤1. In some embodiments, a material of the semiconductor gate 26 may include a p-type doped group III-V layer. In some embodiments, a material of the semiconductor gate 26 may include p-type doped GaN.

The gate conductor 28 can be in contact with the semiconductor gate 26. The gate conductor 28 can be in contact with the electrode 34. The gate conductor 28 can be covered by the passivation layer 22. The gate conductor 28 can be surrounded by the passivation layer 22. The gate conductor 28 may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides)), metal alloys (such as aluminum-copper alloy (Al-Cu)), or other suitable materials.

The passivation layer 22 may include, for example, but is not limited to, oxides and/or nitrides, such as silicon nitride (SiN) and/or silicon oxide (SiO₂). The passivation layer 22 may include silicon nitride and/or silicon oxide formed by a non-plasma film formation process. The passivation layer 24 may include materials similar to those of the passivation layer 22. The passivation layer 24 may include materials identical to those of the passivation layer 22. The passivation layer 24 may include materials different from those of the passivation layer 22.

The electrode 34 can be in contact with the gate conductor 28. The electrode 34 may include a portion embedded within the passivation layer 22. The electrode 34 may include a portion surrounded by the passivation layer 22. The electrode 34 may include materials similar to those of the electrodes 30 and 32.

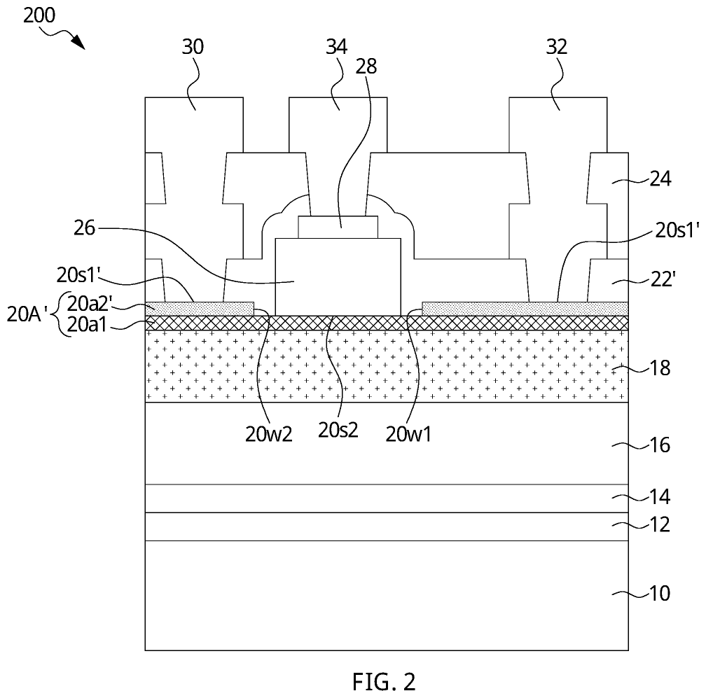

FIG. 2 illustrates a cross-sectional view of a semiconductor device according to some embodiments of the present disclosure. FIG. 2 shows a HEMT 200. The HEMT 200 shown in FIG. 2 can be an enhanced mode (E-mode) HEMT.

The HEMT 200 has a structure similar to that of the HEMT 100 shown in FIG. 1, except that the barrier layer 20A′ of the HEMT 200 includes a trench 20t, and that the passivation layer 22′ has a profile different from the passivation layer 22 of the HEMT 100. The trench 20t can also be referred to as an opening or a recess.

The barrier layer 20A′ includes a layer 20a1 and a layer 20a2′ disposed on the layer 20a1. Referring to FIG. 2, the trench 20t can be defined by sidewalls 20w1 and 20w2 of the layer 20a2′. The trench 20t can expose a portion of the layer 20a1. The trench 20t can expose a surface 20s2 of the layer 20a1.

The semiconductor gate 26 can be disposed within the trench 20t. The semiconductor gate 26 can be in contact with the layer 20a1. The semiconductor gate 26 can be in contact with the surface 20s2 of the layer 20a1. The semiconductor gate 26 can be spaced apart from the sidewall 20w1. The semiconductor gate 26 can be spaced apart from the sidewall 20w2.

Referring to FIG. 2, the layer 20a2′ can be disposed between the electrode 30 and the channel layer 18. The layer 20a2′ can be disposed between the electrode 32 and the channel layer 18. The layer 20a2′ is not disposed between the semiconductor gate 26 and the channel layer 18.

The layer 20a1 may include, for example, but is not limited to, group III nitride, for example, a compound Al_{y}Ga_{(1-y)}N, in which 0≤y≤1. The layer 20a1 may include a compound Al_{y}Ga_{(1-y)}N, in which 0.1≤y≤0.35.

The layer 20a2′ may include, for example, but is not limited to, group III nitride. The layer 20a2′ may include a compound InₓAl₍₁₋ₓ₎N, in which 0≤x≤1. The layer 20a2′ may include a compound InₓAl₍₁₋ₓ₎N, in which 0.1≤x≤0.3. The layer 20a2′ may include a compound InₓAl₍₁₋ₓ₎N, in which 0.1≤x≤0.6.

The material of the layer 20a1 grown under a higher temperature can have good crystal quality. The layer 20a1 grown under a higher temperature can have a relatively smooth upper surface 20s2. The semiconductor gate 26 can be in direct contact with the relatively smooth upper surface 20s2. The relatively smooth upper surface 20s2 may facilitate the formation of the semiconductor gate 26. The material of the layer 20a1 grown under a higher temperature can have high carrier mobility.

The layer 20a2′ can have a relatively low energy bandgap compared to that of the layer 20a1, and thus it would be easier for the electrodes 30 and 32 to be formed on the layer 20a2′. In addition, the layer 20a2′ grown under a lower temperature can have a relatively rough upper surface 20s1′. The relatively rough upper surface 20s1′ may facilitate the formation of the electrodes 30 and 32.

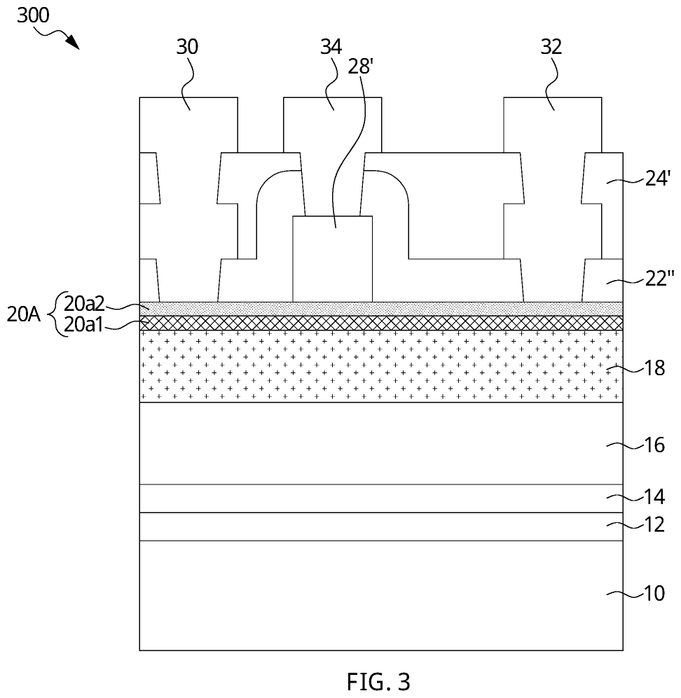

FIG. 3 illustrates a cross-sectional view of a semiconductor device according to some embodiments of the present disclosure. FIG. 3 shows an HEMT 300. The HEMT 300 shown in FIG. 3 can be a depletion-mode (D-mode) HEMT.

The HEMT 300 has a structure similar to that of the HEMT 100 shown in FIG. 1, except that the HEMT 300 does not include a semiconductor gate 26, and that the passivation layer 22″ has a profile different from the passivation layer 22 of the HEMT 100. Referring to FIG. 3, the HEMT 300 includes a gate conductor 28′ disposed on the barrier layer 20A. The gate conductor 28′ can be in direct contact with the barrier layer 20A. The gate conductor 28′ can be in direct contact with the layer 20a2.

The gate conductor 28′ can be covered by the passivation layer 22″. The gate conductor 28′ can be surrounded by the passivation layer 22″. The gate conductor 28′ can be embedded in the passivation layer 22″.

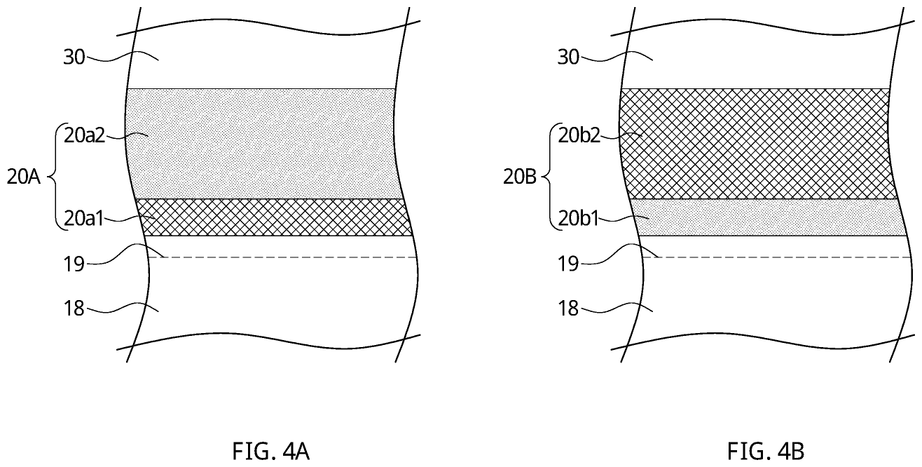

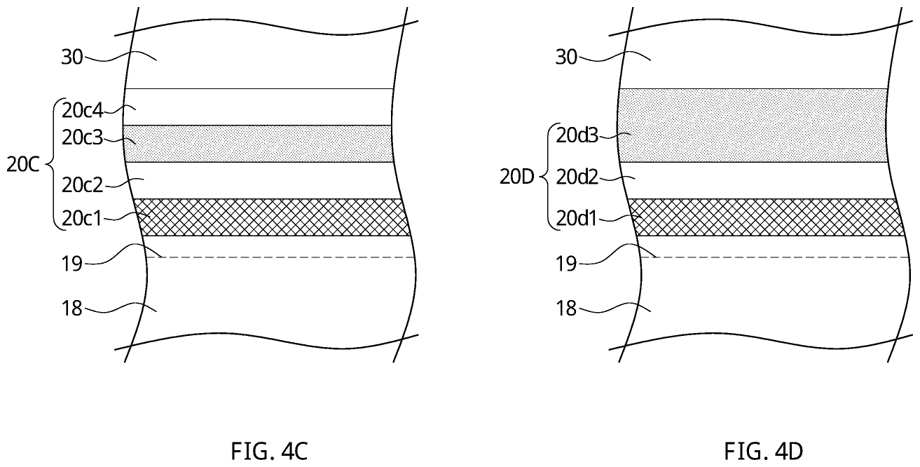

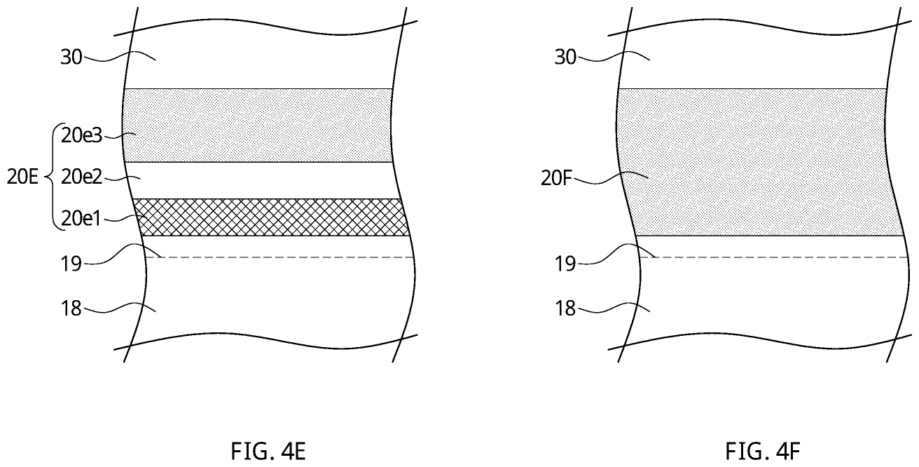

FIG. 4A illustrates a semiconductor stack and the structural relationship between an electrode and the channel layer, according to some embodiments of the present disclosure. FIG. 4A shows the barrier layer 20A (i.e., a semiconductor stack) and the structural relationship between the electrode 30 and the channel layer 18. The barrier layer 20A is disposed between the electrode 30 and the channel layer 18. The barrier layer 20A is sandwiched by the electrode 30 and the channel layer 18. A 2DEG region 19 can be formed in the channel layer 18 for providing a channel for the carriers.

The barrier layer 20A shown in FIG. 4A can be applied to the HEMT 100 of FIG. 1. The barrier layer 20A shown in FIG. 4A can be applied to the HEMT 200 of FIG. 2. The barrier layer 20A shown in FIG. 4A can be applied to the HEMT 300 of FIG. 3.

The barrier layer 20A includes a layer 20a1 and a layer 20a2 disposed on the layer 20a1. The layer 20a1 may include a compound Al_{y}Ga_{(1-y)}N, in which 0≤y≤1. The layer 20a1 may include a compound Al_{y}Ga_{(1-y)}N, in which 0.1≤y≤0.35. The layer 20a2 may include a compound InₓAl₍₁₋ₓ₎N, in which 0≤x≤1. The layer 20a2 may include a compound InₓAl₍₁₋ₓ₎N, in which 0.1≤x≤0.3. The layer 20a2 may include a compound InₓAl₍₁₋ₓ₎N, in which 0.1≤x0.6.

The layer 20a1 can have a thickness in a range of 0.5 to 20 nanometers (nm). The layer 20a2 can have a thickness in a range of 0.5 to 25 nm.

The lattice constant of the layer 20a1 can be different from the lattice constant of the layer 20a2. The lattice constant of the layer 20a1 along the a-axis can be different from the lattice constant of the layer 20a2 along the a-axis. The lattice constant of the layer 20a1 along the a-axis is less than the lattice constant of the layer 20a2 along the a-axis.

The lattice constant along the a-axis of the layer 20a1 ranges from approximately 3.1 Å to approximately 3.18 Å. The lattice constant along the a-axis of the layer 20a2 ranges from approximately 3.2 Å to approximately 3.5 Å.

FIG. 4B illustrates a semiconductor stack and the structural relationship between an electrode and the channel layer, according to some embodiments of the present disclosure. FIG. 4B shows the barrier layer 20B (i.e., a semiconductor stack) and the structural relationship between the electrode 30 and the channel layer 18. The barrier layer 20B is disposed between the electrode 30 and the channel layer 18. The barrier layer 20B is sandwiched by the electrode 30 and the channel layer 18. A 2DEG region 19 can be formed in the channel layer 18 for providing a channel for the carriers.

The barrier layer 20B shown in FIG. 4B can be applied to the HEMT 100 of FIG. 1. The barrier layer 20B shown in FIG. 4B can be applied to the HEMT 200 of FIG. 2. The barrier layer 20B shown in FIG. 4B can be applied to the HEMT 300 of FIG. 3.

The barrier layer 20B includes a layer 20b1 and a layer 20b2 disposed on the layer 20b1. The layer 20b1 may include a compound InₓAl₍₁₋ₓ₎N, in which 0≤x≤1. The layer 20b1 may include a compound InₓAl₍₁₋ₓ₎N, in which 0.1≤x≤0.3. The layer 20b1 may include a compound InₓAl₍₁₋ₓ₎N, in which 0.1≤x0.6. The layer 20b2 may include a compound Al_{y}Ga_{(1-y)}N, in which 0≤y1. The layer 20b2 may include a compound Al_{y}Ga_{(1-y)}N, in which 0.1≤y0.35.

The layer 20b1 can have a thickness in a range of 0.5 to 25 nm. The layer 20b2 can have a thickness in a range of 0.5 to 20 nanometers (nm).

The lattice constant of the layer 20b1 can be different from the lattice constant of the layer 20b2. The lattice constant of the layer 20b1 along the a-axis can be different from the lattice constant of the layer 20b2 along the a-axis. The lattice constant of the layer 20b1 along the a-axis is greater than the lattice constant of the layer 20b2 along the a-axis.

The lattice constant along the a-axis of the layer 20b1 ranges from approximately 3.2 Å to approximately 3.5 Å. The lattice constant along the a-axis of the layer 20b2 ranges from approximately 3.1 Å to approximately 3.18 Å.

Referring to FIG. 4B, the layer 20b1 can be in direct contact with the channel layer 18. The layer 20b2 can be in direct contact with the electrode 30. Due to the materials of the layer 20b2, the growth temperature of the layer 20b2 may be greater than that of the layer 20b1. As a result, some materials of the layer 20b1 may be precipitated in the layer 20b1 during the formation of the layer 20b2. For example, indium cluster may be precipitated in the layer 20b1 during the formation of the layer 20b2. The indium cluster generated in the layer 20b1 can adversely affect the performance or reliability of the HEMT produced.

The precipitation of the indium cluster can be prevented if the growth temperature of the layer 20b2 is lower. Nevertheless, a lower growth temperature will adversely affect the crystal quality of the layer 20b2, and as a result degrade the carrier mobility of the HEMT produced.

FIG. 4C illustrates a semiconductor stack and the structural relationship between an electrode and the channel layer, according to some embodiments of the present disclosure. FIG. 4C shows the barrier layer 20C (i.e., a semiconductor stack) and the structural relationship between the electrode 30 and the channel layer 18. The barrier layer 20C is disposed between the electrode 30 and the channel layer 18. The barrier layer 20C is sandwiched by the electrode 30 and the channel layer 18. A 2DEG region 19 can be formed in the channel layer 18 for providing a channel for the carriers.

The barrier layer 20C shown in FIG. 4C can be applied to the HEMT 100 of FIG. 1. The barrier layer 20C shown in FIG. 4C can be applied to the HEMT 200 of FIG. 2. The barrier layer 20C shown in FIG. 4C can be applied to the HEMT 300 of FIG. 3.

The barrier layer 20C includes layers 20c1, 20c2, 20c3 and 20c4. The layer 20c2 can be disposed on and in contact with the layer 20c1. The layer 20c3 can be disposed on and in contact with the layer 20c2. The layer 20c4 can be disposed on and in contact with the layer 20c3.

The layer 20c1 may include a compound Al_{y}Ga_{(1-y)}N, in which 0≤y1. The layer 20c3 may include a compound InₓAl₍₁₋ₓ₎N, in which 0≤x≤1. The layer 20c3 may include a compound InₓAl₍₁₋ₓ₎N, in which 0.1≤x≤0.3. The layer 20c3 may include a compound InₓAl₍₁₋ₓ₎N, in which 0.1≤x0.6. The layer 20c2 and the layer 20c4 may include the same materials. The layer 20c2 may include a compound GaN. The layer 20c4 may include a compound GaN. The layer 20c2 and the layer 20c4 can also be referred to as a nitride semiconductor layer if they contain nitride.

The layer 20c1 can have a thickness in a range of 0.5 to 20 nanometers (nm). The layer 20c3 can have a thickness in a range of 0.5 to 25 nm. The layer 20c2 can have a thickness in a range of 0 to 3 nm. The layer 20c4 can have a thickness in a range of 0 to 3 nm. The thickness of the layer 20c2 can be substantially identical to that of the layer 20c4. The thickness of the layer 20c2 can be different from that of the layer 20c4.

The lattice constant of the layer 20c1 can be different from the lattice constant of the layer 20c3. The lattice constant of the layer 20c1 along the a-axis can be different from the lattice constant of the layer 20c3 along the a-axis. The lattice constant of the layer 20c1 along the a-axis is less than the lattice constant of the layer 20c3 along the a-axis.

The lattice constant along the a-axis of the layer 20c1 ranges from approximately 3.1 Å to approximately 3.18 Å. The lattice constant along the a-axis of the layer 20c3 ranges from approximately 3.2 Å to approximately 3.5 Å.

A lattice constant of the layer 20c2 along the a-axis can be different from that of the layer 20c1. A lattice constant of the layer 20c2 along the a-axis can be different from that of the layer 20c3. A lattice constant of the layer 20c2 along the a-axis can be approximately 3.189 Å.

A lattice constant of the layer 20c4 along the a-axis can be different from that of the layer 20c1. A lattice constant of the layer 20c4 along the a-axis can be different from that of the layer 20c3. A lattice constant of the layer 20c4 along the a-axis can be approximately 3.189 Å.

The layer 20c2 may compensate for the defects of the bottom surface of the layer 20c3. The layer 20c4 may compensate for the defects of the upper surface of the layer 20c3. Nevertheless, due to the characteristics of the materials of the layer 20c4, it may be relatively difficult for the electrode 30 to be disposed on the layer 20c4. Furthermore, additional steps such as passivation treatment may be required during the HEMT manufacturing because oxides such as Ga₂O₃ may be easily generated from the materials of the layer 20c4.

Furthermore, a channel for electrons can be formed between the interface of the layers 20c1 and 20c2 because the energy bandgap of the layer 20c2 may be lower than that of the layer 20c1. As a result, current leakage may occur between the interface of the layers 20c1 and 20c2. The current leakage may adversely affect the performance or reliability of the HEMT produced.

Likewise, a channel for electrons can be formed between the interface of the layers 20c2 and 20c3 because the energy bandgap of the layer 20c2 may be lower than that of the layer 20c3. As a result, current leakage may occur between the interface of the layers 20c2 and 20c3. The current leakage may adversely affect the performance or reliability of the HEMT produced.

Similarly, a channel for electrons can be formed between the interface of the layers 20c3 and 20c4 because the energy bandgap of the layer 20c4 may be lower than that of the layer 20c3. As a result, current leakage may occur between the interface of the layers 20c3 and 20c4. The current leakage may adversely affect the performance or reliability of the HEMT produced.

FIG. 4D illustrates a semiconductor stack and the structural relationship between an electrode and the channel layer, according to some embodiments of the present disclosure. FIG. 4D shows the barrier layer 20D (i.e., a semiconductor stack) and its structural relationships between the electrode 30 and the channel layer 18. The barrier layer 20D is disposed between the electrode 30 and the channel layer 18. The barrier layer 20D is sandwiched by the electrode 30 and the channel layer 18. A 2DEG region 19 can be formed in the channel layer 18 for providing a channel for the carriers.

The barrier layer 20D shown in FIG. 4D can be applied to the HEMT 100 of FIG. 1. The barrier layer 20D shown in FIG. 4D can be applied to the HEMT 200 of FIG. 2. The barrier layer 20D shown in FIG. 4D can be applied to the HEMT 300 of

FIG. 3.

The barrier layer 20D includes layers 20d1, 20d2 and 20d3. The layer 20d2 can be disposed on and in contact with the layer 20d1. The layer 20d3 can be disposed on and in contact with the layer 20d2.

The layer 20d1 may include a compound Al_{y}Ga_{(1-y)}N, in which y≤1. The layer 20d3 may include a compound InₓAl₍₁₋ₓ₎N, in which x≤1. The layer 20d3 may include a compound InₓAl₍₁₋ₓ₎N, in which 0.1≤x≤0.3. The layer 20d2 may include a compound GaN.

The layer 20d1 can have a thickness in a range of 0.5 to 20 nanometers (nm). The layer 20d2 can have a thickness in a range of 0 to 3 nm. The layer 20d3 can have a thickness in a range of 0.5 to 25 nm.

The lattice constant of the layer 20d1 can be different from the lattice constant of the layer 20d3. The lattice constant of the layer 20d1 along the a-axis can be different from the lattice constant of the layer 20d3 along the a-axis. The lattice constant of the layer 20d1 along the a-axis is less than the lattice constant of the layer 20d3 along the a-axis.

The lattice constant along the a-axis of the layer 20d1 ranges from approximately 3.1 Å to approximately 3.18 Å. The lattice constant along the a-axis of the layer 20d3 ranges from approximately 3.2 Å to approximately 3.5 Å.

A lattice constant of the layer 20d2 along the a-axis can be different from that of the layer 20d1. A lattice constant of the layer 20d2 along the a-axis can be different from that of the layer 20d3. A lattice constant of the layer 20d2 along the a-axis can be approximately 3.189 Å.

Channel for electrons can be formed between the interface of the layers 20d1 and 20d2 because the energy bandgap of the layer 20d2 may be lower than that of the layer 20d1. As a result, current leakage may occur between the interface of the layers 20d1 and 20d2. The current leakage may adversely affect the performance or reliability of the HEMT produced.

Likewise, a channel for electrons can be formed between the interface of the layers 20d2 and 20d3 because the energy bandgap of the layer 20d2 may be lower than that of the layer 20d3. As a result, current leakage may occur between the interface of the layers 20d2 and 20d3. The current leakage may adversely affect the performance or reliability of the HEMT produced.

FIG. 4E illustrates a semiconductor stack and the structural relationship between an electrode and the channel layer, according to some embodiments of the present disclosure. FIG. 4E shows the barrier layer 20E (i.e., a semiconductor stack) and the structural relationship between the electrode 30 and the channel layer 18. The barrier layer 20E is disposed between the electrode 30 and the channel layer 18. The barrier layer 20E is sandwiched by the electrode 30 and the channel layer 18. A 2DEG region 19 can be formed in the channel layer 18 for providing a channel for the carriers.

The barrier layer 20E shown in FIG. 4E can be applied to the HEMT 100 of FIG. 1. The barrier layer 20E shown in FIG. 4E can be applied to the HEMT 200 of FIG. 2. The barrier layer 20E shown in FIG. 4E can be applied to the HEMT 300 of FIG. 3.

The barrier layer 20E includes layers 20e1, 20e2 and 20e3. The layer 20e2 can be disposed on and in contact with the layer 20e1. The layer 20e3 can be disposed on and in contact with the layer 20e2.

The layer 20e1 may include a compound Al_{y}Ga_{(1-y)}N, in which y≤1. The layer 20e3 may include a compound InₓAl₍₁₋ₓ₎N, in which x≤1. The layer 20e3 may include a compound InₓAl₍₁₋ₓ₎N, in which 0.1≤x≤0.3. The layer 20e2 may include a compound AlN. The layer 20e2 can also be referred to as a nitride semiconductor layer if the layer 20e2 contains nitride.

The layer 20e1 can have a thickness in a range of 0.5 to 20 nanometers (nm). The layer 20e2 can have a thickness in a range of 0 to 3 nm. The layer 20e3 can have a thickness in a range of 0.5 to 25 nm. The layer 20e2 can be used as an etching-stop layer during the manufacturing of an HEMT.

The lattice constant of the layer 20e1 can be different from the lattice constant of the layer 20e3. The lattice constant of the layer 20e1 along the a-axis can be different from the lattice constant of the layer 20e3 along the a-axis. The lattice constant of the layer 20e1 along the a-axis is less than the lattice constant of the layer 20e3 along the a-axis.

The lattice constant along the a-axis of the layer 20e1 ranges from approximately 3.1 Å to approximately 3.18 Å. The lattice constant along the a-axis of the layer 20e3 ranges from approximately 3.2 Å to approximately 3.5 Å.

A lattice constant of the layer 20e2 along the a-axis can be different from that of the layer 20e1. A lattice constant of the layer 20e2 along the a-axis can be different from that of the layer 20e3. A lattice constant of the layer 20e2 along the a-axis can be approximately 3.112 Å.

FIG. 4F illustrates a barrier layer and the structural relationship between an electrode and the channel layer, according to some embodiments of the present disclosure. FIG. 4F shows the barrier layer 20F and the structural relationship between the electrode 30 and the channel layer 18. The barrier layer 20F is disposed between the electrode 30 and the channel layer 18. The barrier layer 20F is sandwiched by the electrode 30 and the channel layer 18. A 2DEG region 19 can be formed in the channel layer 18 for providing a channel for the carriers.

The barrier layer 20F may include a compound InₓAl₍₁₋ₓ₎N, in which x≤1. The barrier layer 20F may include a compound InₓAl₍₁₋ₓ₎N, in which 0.1≤x≤0.3. The barrier layer 20F can have a thickness in a range of 0.5 to 30 nm.

The barrier layer 20F in direct contact with the channel layer 18 may have some disadvantages though. In the formation of the channel layer 18 and the barrier layer 20F, precursors for several different materials (such as precursors for Al, Ga, In and N) may coexist within the furnace. The precursors for different materials within the furnace may contaminate the channel layer 18 or the barrier layer 20F, and as a result, the performance or reliability of the HEMT produced may be adversely affected.

FIG. 4F proposes a semiconductor structure that using a barrier layer 20F comprising InₓAl₍₁₋ₓ₎N, instead of a conventional barrier layer comprising of AlGaN. Nevertheless, the growth temperature of the barrier layer 20F that includes InₓAl₍₁₋ₓ₎N can be relatively lower than a conventional barrier layer comprising of AlGaN, and thus the crystal quality of the barrier layer 20F can be relatively worse than that of a conventional barrier layer comprising of AlGaN. A relatively worse crystal quality of the barrier layer 20F may adversely affect the performance or reliability of the HEMT produced.

Furthermore, the barrier layer 20F comprising InₓAl₍₁₋ₓ₎N in direct contact with the channel layer 18 (which includes, for example, GaN) may generate surface states and then capture the carriers. As a result, an HEMT having the barrier layer 20F in direct contact with the channel layer 18 may have a relatively low carrier mobility.

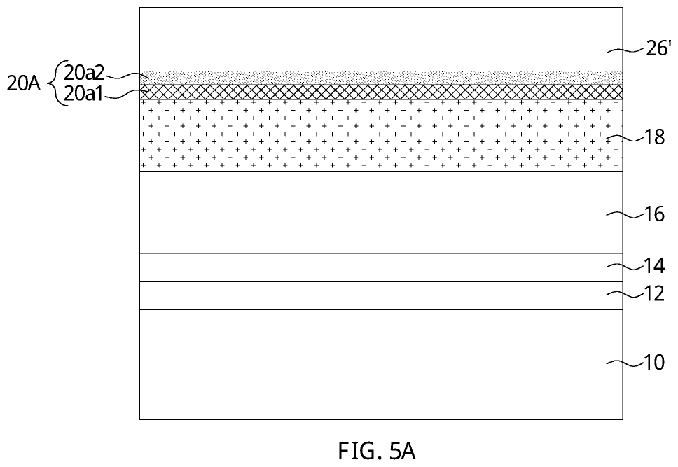

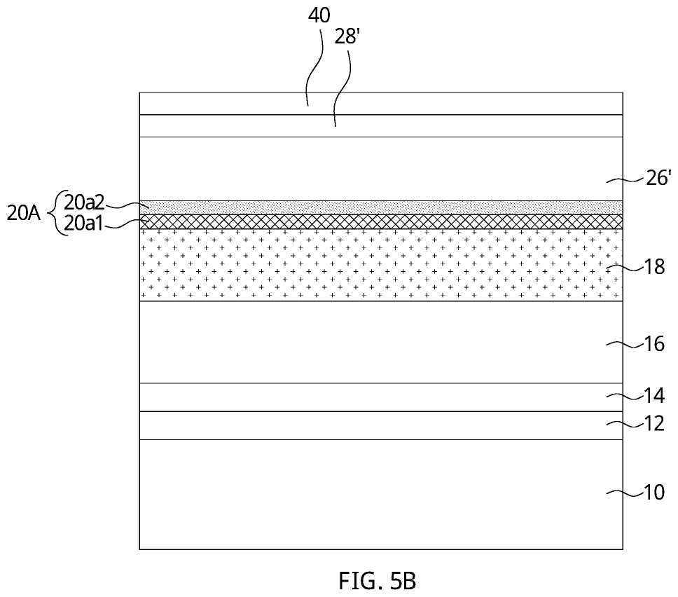

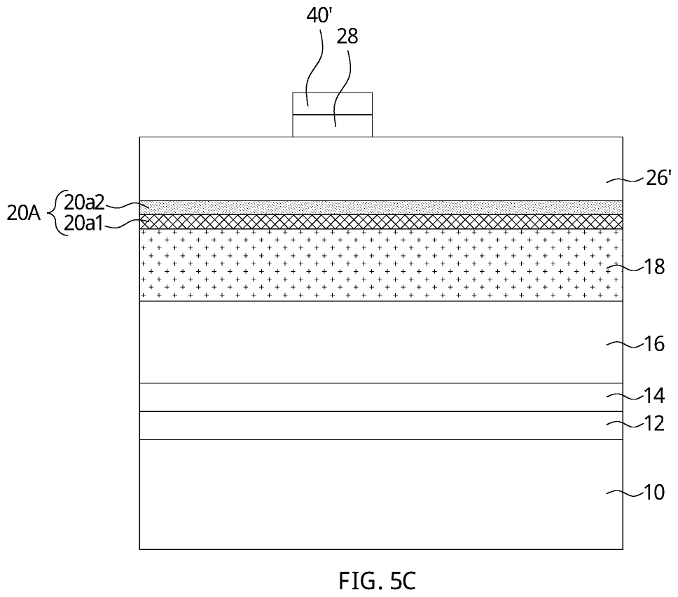

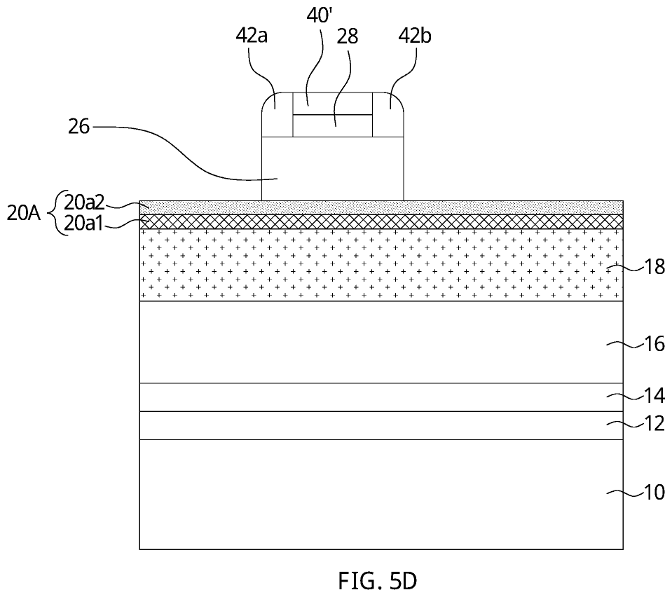

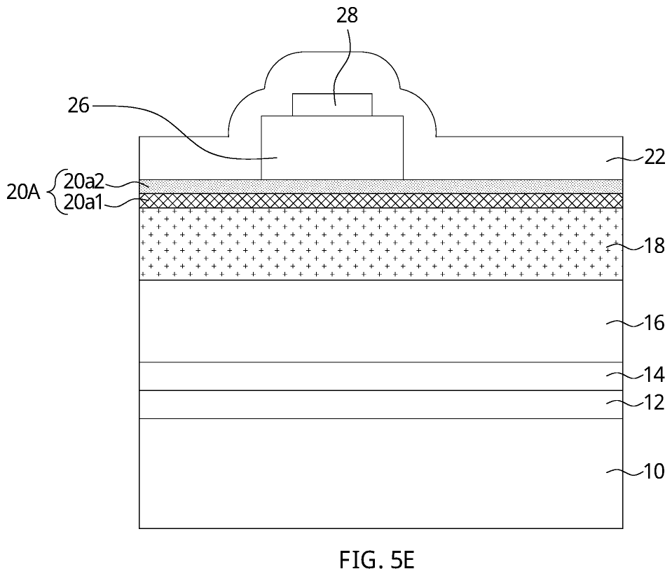

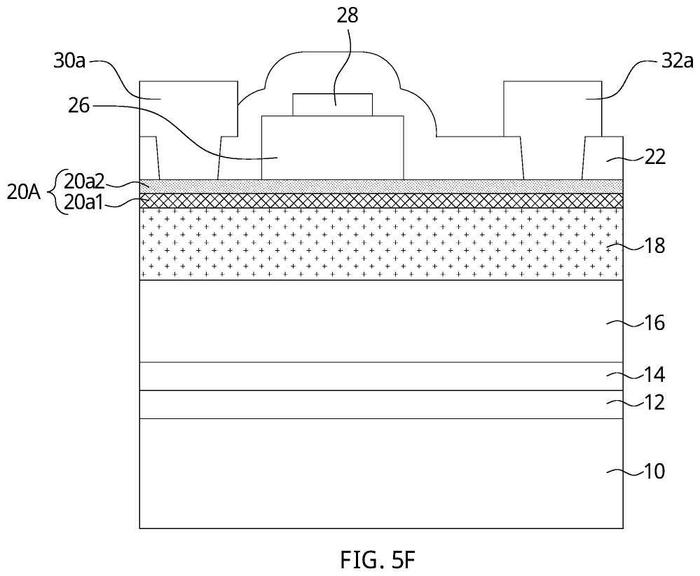

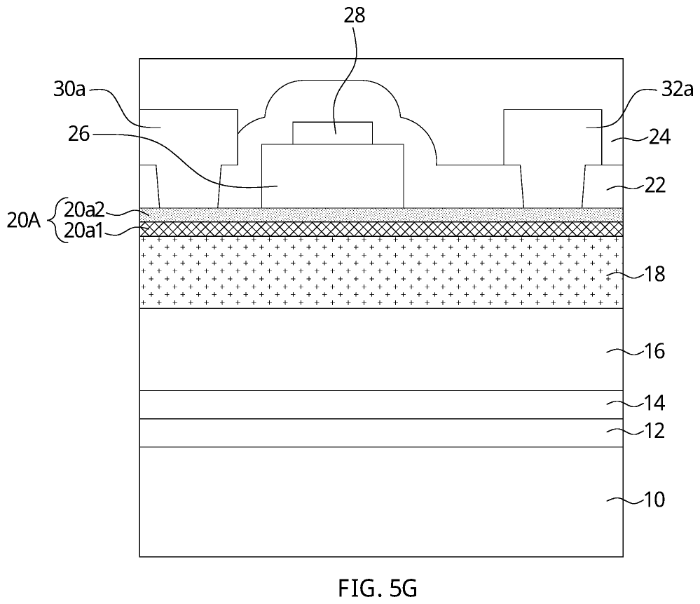

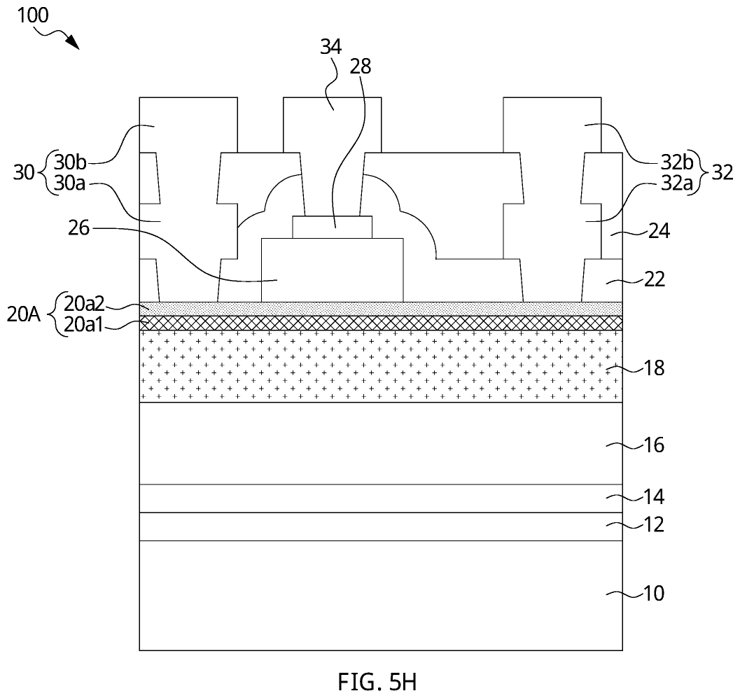

FIGS. 5A, 5B, 5C, 5D, 5E, 5F, 5G and 5H illustrate operations for fabricating a semiconductor device according to some embodiments of the present disclosure. The operations shown in FIGS. 5A, 5B, 5C, 5D, 5E, 5F, 5G and 5H can be performed to produce the HEMT 100 shown in FIG. 1.

Referring to FIG. 5A, a substrate 10 is provided. The substrate 10 may include a silicon material or sapphire. Next, a seed layer 12 is formed on the substrate 10, a buffer layer 14 is formed on the seed layer 12, and an electron blocking layer 16 is formed on the buffer layer 14. A channel layer 18 is formed on the electron blocking layer 16, and then a barrier layer 20A is formed on the channel layer 18. The barrier layer 20A includes a layer 20a1 and a layer 20a2 disposed on the layer 20a1. Next, a semiconductor gate material layer 26′ is formed on the barrier layer 20A.

The substrate 10 may include materials as discussed in accordance with the HEMT 100 of FIG. 1. The seed layer 12 may include materials as discussed in accordance with the HEMT 100 of FIG. 1. The buffer layer 14 may include materials as discussed in accordance with the HEMT 100 of FIG. 1. The electron blocking layer 16 may include materials as discussed in accordance with the HEMT 100 of FIG. 1.

The channel layer 18, the layer 20a1 and the layer 20a2 may include materials as discussed in accordance with the HEMT 100 of FIG. 1. The semiconductor gate material layer 26′ may include materials as discussed in accordance with the semiconductor gate 26 of the HEMT 100 of FIG. 1.

The channel layer 18 may include GaN, the layer 20a1 may include AlGaN, the layer 20a2 may include InAlN, and the semiconductor gate material layer 26′ may include GaN. The channel layer 18, the barrier layer 20A, and/or the semiconductor gate material layer 26′ may be formed by chemical vapor deposition (CVD), physical vapor deposition (PVD), epitaxial growth, or other suitable deposition processes.

Referring to FIG. 5B, a gate conductor material layer 28′ is formed on the semiconductor gate material layer 26′, and a mask layer 40 is formed on the gate conductor material layer 28′. In some embodiments, one or more layers of materials may be deposited by PVD, CVD, and/or other suitable processes to form the gate conductor material layer 28′. The gate conductor material layer 28′ may be formed by sputtering or evaporating a metal material on the semiconductor gate material layer 26′.

Referring to FIG. 5C, a patterning process may be performed on the mask layer 40 and the gate conductor material layer 28′ to form a gate conductor 28. A patterned mask layer 40′ can be first formed above the gate conductor material layer 28′, and then the portions of the gate conductor material layer 28′ that are not covered by the patterned mask layer 40′ can be removed. The gate conductor material layer 28′ may be patterned by dry etching. The gate conductor material layer 28′ may be patterned by wet etching. The etching process conducted on the gate conductor material layer 28′ may stop on the top surface of the semiconductor gate material layer 26′. The etching process conducted on the gate conductor material layer 28′ may continue until the top surface of the semiconductor gate material layer 26′ is exposed.

Referring to FIG. 5D, spacers 42a and 42b are formed adjacent to the patterned mask layer 40′ and the gate conductor 28. Next, the portions of the semiconductor gate material layer 26′ that are not covered by the spacers 42a and 42b and the gate conductor 28 are removed to form the semiconductor gate 26.

The semiconductor gate material layer 26′ may be patterned by dry etching. The semiconductor gate material layer 26′ may be patterned by wet etching. The etching process conducted on the semiconductor gate material layer 26′ may stop on the top surface of the barrier layer 20. The etching process conducted on the semiconductor gate material layer 26′ may continue until the top surface of the barrier layer 20 is exposed.

Referring to FIG. 5E, the spacers 42a and 42b are removed, and the patterned mask layer 40′ is also removed. Next, a passivation layer 22 is disposed to cover the barrier layer 20A, the semiconductor gate 26 and the gate conductor 28. The passivation layer 22 can be conformally formed above the barrier layer 20A, the semiconductor gate 26 and the gate conductor 28. The passivation layer 22 may include, for example, but is not limited to, oxides and/or nitrides, such as silicon nitride (SiN) and/or silicon oxide (SiO₂). The passivation layer 22 may include silicon nitride and/or silicon oxide formed by a non-plasma film formation process.

Referring to FIG. 5F, conductors 30a and 32a can be formed. The conductor 30a can be formed in contact with the barrier layer 20A. The conductor 32a can be formed in contact with the barrier layer 20A. The conductor 30a can be formed in contact with the layer 20a2. The conductor 32a can be formed in contact with the layer 20a2. A portion of the conductor 30a can be surrounded by the passivation layer 22. A portion of the conductor 32a can be surrounded by the passivation layer 22.

The conductors 30a and 32a can be formed using techniques, for example, but not limited to, soldering, welding, crimping, deposition, or electroplating. The conductors 30a and 32a may include, for example, but are not limited to, titanium (Ti), aluminum (Al), Nickel (Ni), Gold (Au), Palladium (Pd), or any combinations or alloys thereof.

Referring to FIG. 5G, a passivation layer 24 is formed. The passivation layer 24 is disposed above and covers the conductors 30a and 32a and the passivation layer 22. The passivation layer 24 may include, for example, but is not limited to, oxides and/or nitrides, such as silicon nitride (SiN) and/or silicon oxide (SiO₂). The passivation layer 24 may include silicon nitride and/or silicon oxide formed by a non-plasma film formation process. The passivation layer 24 may include materials similar to those of the passivation layer 22. The passivation layer 24 may include materials identical to those of the passivation layer 22. The passivation layer 24 may include materials different from those of the passivation layer 22.

Referring to FIG. 5H, conductors 30b and 32b and electrode 34 can be formed. The conductor 30b is formed above and in contact with the conductor 30a. The conductors 30a and 30b form the electrode 30. The conductor 32b is formed above and in contact with the conductor 32a. The conductors 32a and 32b form the electrode 32. The electrodes 30, 32 and 34 are exposed by the passivation layer 24. The electrodes 30, 32 and 34 are not covered by the passivation layer 24.

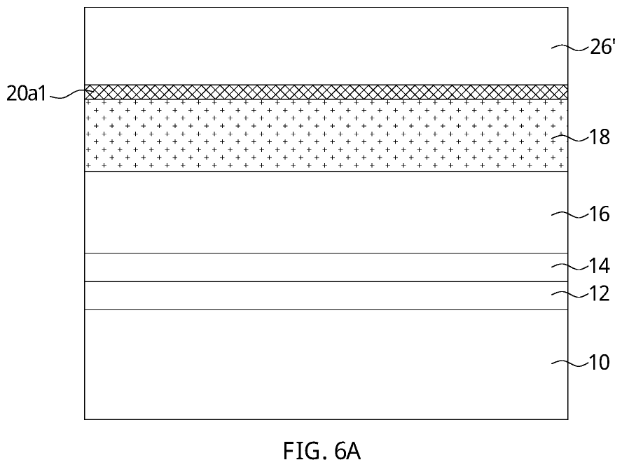

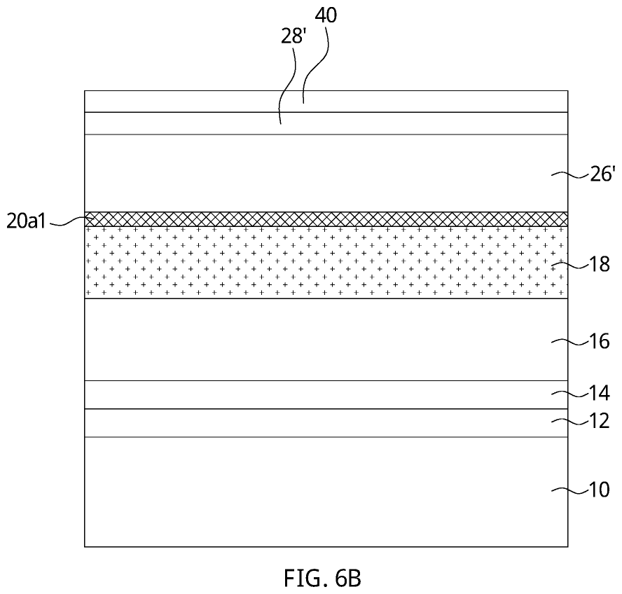

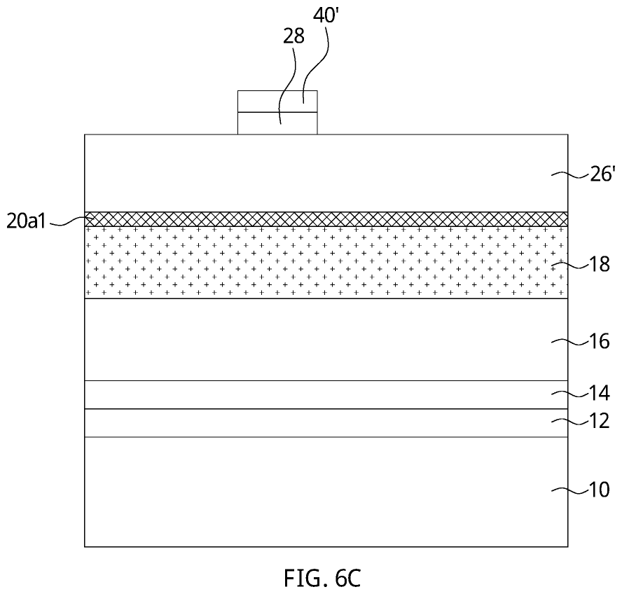

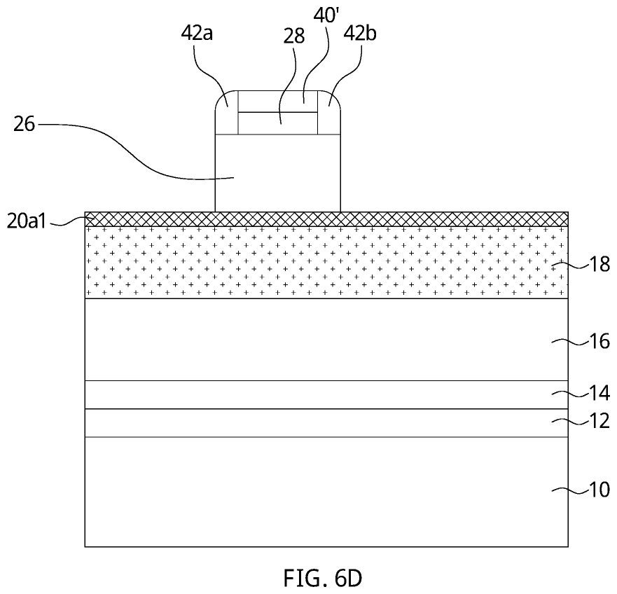

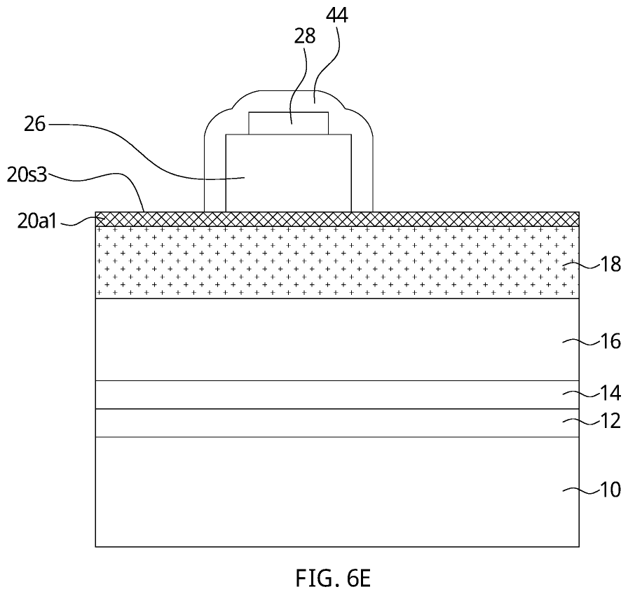

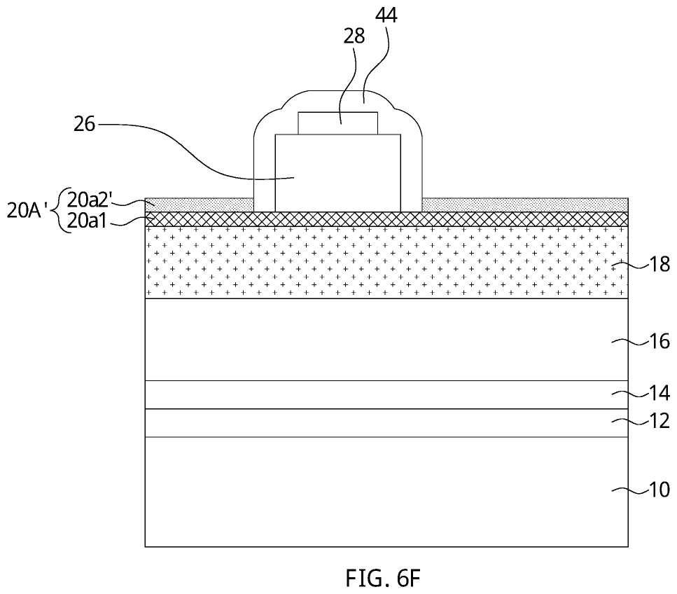

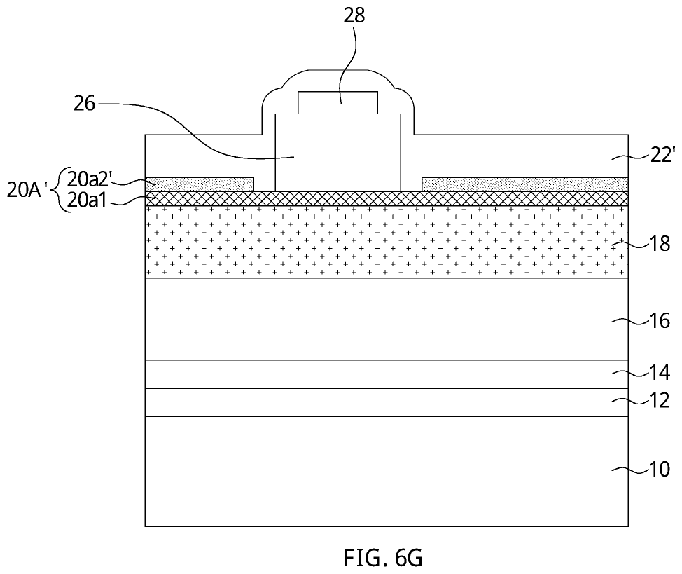

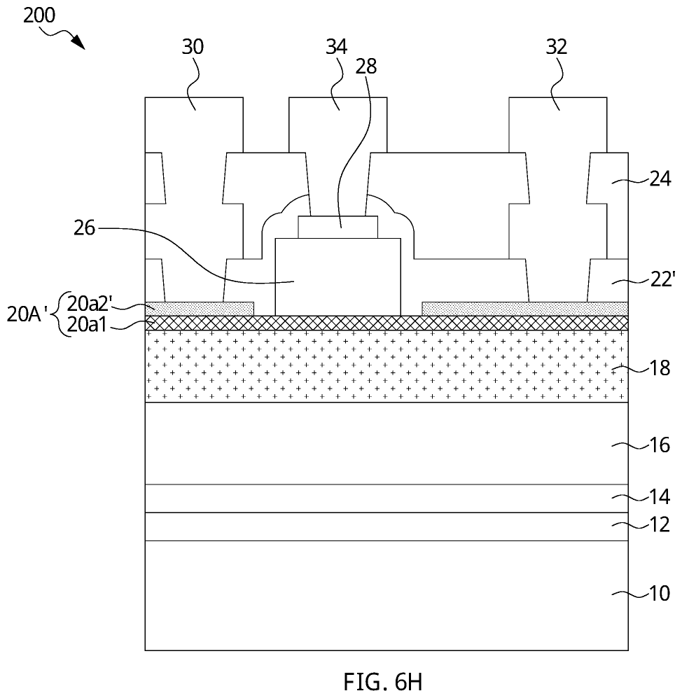

FIGS. 6A, 6B, 6C, 6D, 6E, 6F, 6G and 6H illustrate operations for fabricating a semiconductor device according to some embodiments of the present disclosure. The operations shown in FIGS. 6A, 6B, 6C, 6D, 6E, 6F, 6G and 6H can be performed to produce the HEMT 200 shown in FIG. 2.

Referring to FIG. 6A, a substrate 10 is provided. The substrate 10 may include a silicon material or sapphire. Next, a seed layer 12 is formed on the substrate 10, a buffer layer 14 is formed on the seed layer 12, and an electron blocking layer 16 is formed on the buffer layer 14. A channel layer 18 is formed on the electron blocking layer 16, and then a layer 20a1 is formed on the channel layer 18. Next, a semiconductor gate material layer 26′ is formed on the layer 20a1.

The substrate 10 may include materials as discussed in accordance with the

HEMT 100 of FIG. 1. The seed layer 12 may include materials as discussed in accordance with the HEMT 100 of FIG. 1. The buffer layer 14 may include materials as discussed in accordance with the HEMT 100 of FIG. 1. The electron blocking layer 16 may include materials as discussed in accordance with the HEMT 100 of FIG. 1.

The channel layer 18 and the layer 20a1 may include materials as discussed in accordance with the HEMT 100 of FIG. 1. The semiconductor gate material layer 26′ may include materials as discussed in accordance with the semiconductor gate 26 of the HEMT 100 of FIG. 1.

In some embodiments, a material of the channel layer 18 may include GaN, a material of the layer 20a1 may include AlGaN, and a material of the semiconductor gate material layer 26′ may include GaN. The channel layer 18, the layer 20a1, and/or the semiconductor gate material layer 26′ may be formed by chemical vapor deposition (CVD), physical vapor deposition (PVD), epitaxial growth, or other suitable deposition processes.

Referring to FIG. 6B, a gate conductor material layer 28′ is formed on the semiconductor gate material layer 26′, and a mask layer 40 is formed on the gate conductor material layer 28′. In some embodiments, one or more layers of materials may be deposited by PVD, CVD, and/or other suitable processes to form the gate conductor material layer 28′. The gate conductor material layer 28′ may be formed by sputtering or evaporating a metal material on the semiconductor gate material layer 26′.

Referring to FIG. 6C, a patterning process may be performed on the mask layer 40 and the gate conductor material layer 28′ to form a gate conductor 28. A patterned mask layer 40′ can be first formed above the gate conductor material layer 28′, and then the portions of the gate conductor material layer 28′ that are not covered by the patterned mask layer 40′ can be removed. The gate conductor material layer 28′ may be patterned by dry etching. The gate conductor material layer 28′ may be patterned by wet etching. The etching process conducted on the gate conductor material layer 28′ may stop on the top surface of the semiconductor gate material layer 26′. The etching process conducted on the gate conductor material layer 28′ may continue until the top surface of the semiconductor gate material layer 26′ is exposed.

Referring to FIG. 6D, spacers 42a and 42b are formed adjacent to the patterned mask layer 40′ and the gate conductor 28. Next, the portions of the semiconductor gate material layer 26′ that are not covered by the spacers 42a and 42b and the gate conductor 28 are removed to form the semiconductor gate 26.

The semiconductor gate material layer 26′ may be patterned by dry etching. The semiconductor gate material layer 26′ may be patterned by wet etching. The etching process conducted on the semiconductor gate material layer 26′ may stop on the top surface of the layer 20a1. The etching process conducted on the semiconductor gate material layer 26′ may continue until the top surface of the layer 20a1 is exposed.

Referring to FIG. 6E, the spacers 42a and 42b are removed, and the patterned mask layer 40′ is also removed. Next, a mask layer 44 is disposed to cover the semiconductor gate 26 and the gate conductor 28. The mask layer 44 can be conformally formed above the semiconductor gate 26 and the gate conductor 28. The mask layer 44 may expose a surface 20s3 of the layer 20a1.

Referring to FIG. 6F, a layer 20a2′ is formed on the surface 20s3 of the layer 20a1. The layer 20a2′ may include materials similar or identical to those of the layer 20a2 of the HEMT 100 of FIG. 1. The layer 20a2′ may be formed by chemical vapor deposition (CVD), physical vapor deposition (PVD), epitaxial growth, or other suitable deposition processes. The layer 20a1 and the layer 20a2′ can be referred to as a semiconductor stack. The layer 20a1 and the layer 20a2′ can be referred to as a barrier layer 20A′.

Referring to FIG. 6G, the mask layer 44 is removed, and then a passivation layer 22 is disposed to cover the barrier layer 20A, the semiconductor gate 26 and the gate conductor 28. The passivation layer 22 can be conformally formed above the barrier layer 20A, the semiconductor gate 26 and the gate conductor 28. The passivation layer 22 may include, for example, but is not limited to, oxides and/or nitrides, such as silicon nitride (SiN) and/or silicon oxide (SiO₂). The passivation layer 22 may include silicon nitride and/or silicon oxide formed by a non-plasma film formation process.

Referring to FIG. 6H, electrodes 30 and 32 are formed to be in contact with the layer 20a2′, and electrode 34 is formed to be in contact with the gate conductor 28. A passivation layer 24 is formed to cover a portion of each of the electrodes 30, 32 and 34. The passivation layer 24 exposes a portion of each of the electrodes 30, 32 and 34.

The HEMT 300 can be formed by operations similar to those shown in FIGS. 5A, 5B, 5C, 5D, 5E, 5F, 5G and 5H, except that the semiconductor gate material layer 26′ is omitted during the operations shown in FIGS. 5A, 5B, 5C, 5D, 5E, 5F, 5G and 5H.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conjunction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device, comprising:
a substrate;
a first nitride semiconductor layer disposed above the substrate;
a semiconductor stack disposed on and in contact with the first nitride semiconductor layer; and
a first electrode in contact with the semiconductor stack,
wherein the semiconductor stack comprises a first layer and a second layer, and a lattice constant of the first layer along an a-axis is less than the second layer.

2. The semiconductor device according to claim 1, wherein the first layer comprises Al_{y}Ga_{(1-y)}M, and the value y ranges from 0 to 1.

3. The semiconductor device according to claim 1, wherein the second layer comprises InₓAl₍₁₋ₓ₎N, and the value x ranges from 0 to 1.

4. The semiconductor device according to claim 1, wherein the lattice constant along the a-axis of the first layer ranges from approximately 3.1 Å to approximately 3.18 Å.

5. The semiconductor device according to claim 1, wherein the lattice constant along the a-axis of the second layer ranges from approximately 3.2 Å to approximately 3.5 Å.

6. The semiconductor device according to claim 1, wherein the first layer is in contact with the first nitride semiconductor layer.

7. The semiconductor device according to claim 1, wherein the second layer is in contact with the first electrode.

8. The semiconductor device according to claim 1, wherein the semiconductor stack further comprises a third layer interposed between the first layer and the second layer, the a-axis lattice constant of the third layer is approximately 3.189 Å.

9. The semiconductor device according to claim 1, wherein the semiconductor stack further comprises a third layer interposed between the first layer and the second layer, the a-axis lattice constant of the third layer is approximately 3.112 Å.

10. The semiconductor device according to claim 8, wherein the semiconductor stack further comprises a fourth layer interposed between the second layer and the first electrode.

11. The semiconductor device according to claim 10, wherein the third layer comprises same material to the fourth layer.

12. The semiconductor device according to claim 1, wherein the second layer comprises a trench exposing a portion of the first layer.

13. The semiconductor device according to claim 12, further comprising a doped group III-V layer in contact with the exposed portion of the first layer.

14. The semiconductor device according to claim 12, further comprising a doped group III-V layer disposed within the trench and spaced apart from a first sidewall of the trench.

15. A semiconductor device, comprising:
a substrate;
a first nitride semiconductor layer disposed above the substrate;
a semiconductor stack disposed on the channel layer; and
a first electrode in contact with the semiconductor stack; wherein the semiconductor stack comprises a second nitride semiconductor layer and a third nitride semiconductor layer, and a bandgap of the second nitride semiconductor layer is different from a bandgap of the third nitride semiconductor layer.

16. The semiconductor device according to claim 15, wherein the second nitride semiconductor layer comprises aluminum and the third nitride semiconductor layer comprises aluminum and Indium.

17. The semiconductor device according to claim 15, wherein the second nitride semiconductor layer comprises aluminum gallium nitride, and the third nitride semiconductor layer comprises Indium aluminum nitride.

18. The semiconductor device according to claim 15, wherein the second nitride semiconductor layer comprises Al_{y}Ga_{(1-y)}N, and the value y ranges from 0.1 to 0.35.

19. The semiconductor device according to claim 15, wherein the third nitride semiconductor layer comprises InₓAl₍₁₋ₓ₎N, and the value x ranges from 0.1 to 0.6.

20. The semiconductor device according to claim 15, wherein the a-axis lattice constant of the second nitride semiconductor layer is less than the a-axis lattice constant of the third nitride semiconductor layer.

21. The semiconductor device according to claim 15, wherein the semiconductor stack further comprises a fourth nitride semiconductor layer interposed between the second nitride semiconductor layer and the third nitride semiconductor layer, the fourth nitride semiconductor layer comprises Gallium nitride.

22. The semiconductor device according to claim 15, wherein the semiconductor stack further comprises a fourth nitride semiconductor layer interposed between the second nitride semiconductor layer and the third nitride semiconductor layer, the fourth nitride semiconductor layer comprises aluminum nitride.

23. A method for fabricating a semiconductor device, comprising:
providing a semiconductor structure having a substrate and a channel layer above the substrate;
providing a first nitride semiconductor layer on the channel layer;
providing a second nitride semiconductor layer above the first barrier layer; and
providing an electrode in contact with the second nitride semiconductor layer; wherein the first nitride semiconductor layer comprises AlₓGa₁₋ₓN, and the second nitride semiconductor layer comprises In_{y}Al_{1-y}N.

24. The method according to claim 23, wherein the value x ranges from 0.1 to 0.35, and the value y ranges from 0.1 to 0.6.

25. The method according to claim 23, further comprising providing a third nitride semiconductor layer comprising Gallium nitride interposed between the first nitride semiconductor layer and the second nitride semiconductor layer.

26. The method according to claim 23, further comprising providing a third nitride semiconductor layer comprising aluminum nitride interposed between the first nitride semiconductor layer and the second nitride semiconductor layer.
